(19) United States
(12) Patent Application Publication
(10) Pub. No.: US 2024/0315036 A1
(43) Pub. Date: Sep. 19, 2024

(54) SEMICONDUCTOR MEMORY DEVICE AND METHOD FOR MANUFACTURING THE SAME

(71) Applicant: Kioxia Corporation, Tokyo (JP)

(72) Inventors: Shin ISHIMATSU, Nagoya Aichi (JP); Tatsunori ISOGAI, Yokkaichi Mie (JP); Masaki NOGUCHI, Yokkaichi Mie (JP); Hiroyuki YAMASHITA, Yokkaichi Mie (JP); Wataru MATSUURA, Yokkaichi Mie (JP); Daisuke NISHIDA, Mie Mie (JP); Junichi KANEYAMA, Yokkaichi Mie (JP); Tomoyuki TAKEMOTO, Nagoya Aichi (JP)

(21) Appl. No.: 18/593,502

(22) Filed: Mar. 1, 2024

(30) Foreign Application Priority Data
Mar. 16, 2023 (JP) 2023-041497

(51) Int. Cl. H10B 43/35; G11C 16/04; H10B 41/27; H10B 41/35; H10B 43/27

(52) U.S. Cl. CPC H10B 43/35; G11C 16/0483; H10B 41/27; H10B 41/35; H10B 43/27

(57) ABSTRACT

According to one embodiment, a semiconductor memory device includes a stacked film in which a plurality of silicon oxide layers, one of which having a film density of 2.3 g/cm³ or more, and a plurality of conductive layers, are alternately stacked in a first direction, and a memory pillar that penetrates the stacked film in the first direction, wherein a plurality of memory cells is provided in the memory pillar.

### CROSS-REFERENCE TO RELATED APPLICATION

This application is based upon and claims the benefit of priority from Japanese Patent Application No. 2023-041497, filed Mar. 16, 2023, the entire contents of which are incorporated herein by reference.

### FIELD

Embodiments described herein relate generally to a semiconductor memory device and a method for manufacturing the same.

### BACKGROUND

A large-capacity non-volatile memory has been developed. This large-capacity non-volatile memory is capable of low-voltage and low-current operation, high-speed switching, and miniaturization and high integration of memory cells.

In a memory cell array provided in a large-capacity non-volatile memory, a large number of metal wirings called bit lines and word lines are arranged. A voltage is applied to a bit line and a word line connected to the cell, and data is written into one memory cell corresponding to the bit line and the word line. A semiconductor memory device has been proposed in which memory cells are arranged three-dimensionally and includes a stacked film in which conductive layers and insulating layers are alternately stacked to serve as such word lines.

### DESCRIPTION OF THE DRAWINGS

FIG. 1 is a block diagram of a semiconductor memory device according to a first embodiment.

FIG. 2 is an equivalent circuit diagram of the semiconductor memory device according to the first embodiment.

FIG. 3 is a schematic cross-sectional view of a main part of the semiconductor memory device according to the first embodiment.

FIG. 4 is a schematic cross-sectional view showing a method for manufacturing a semiconductor memory device according to the first embodiment.

FIG. 5 is a schematic cross-sectional view showing the method for manufacturing a semiconductor memory device according to the first embodiment.

FIG. 6 is a schematic cross-sectional view showing the method for manufacturing a semiconductor memory device according to the first embodiment.

FIG. 7 is a schematic cross-sectional view showing the method for manufacturing a semiconductor memory device according to the first embodiment.

FIG. 8 is a schematic cross-sectional view showing a main part of the semiconductor memory device according to a second embodiment.

FIG. 9 is a schematic cross-sectional view showing a method for manufacturing a semiconductor memory device according to the second embodiment.

### DETAILED DESCRIPTION

Embodiments provide a semiconductor memory device having high reliability.

In general, according to embodiments, a semiconductor memory device includes a stacked film in which a plurality of silicon oxide layers, one of which having a film density of 2.3 g/cm³ or more, and a plurality of conductive layers, are alternately stacked in a first direction, and a memory pillar that penetrates the stacked film in the first direction, wherein a plurality of memory cells is provided in the memory pillar.

Hereinafter, embodiments will be described with reference to the accompanying drawings. In the drawings, the same or similar parts are denoted by the same or similar reference numerals.

In the present specification, in order to indicate a positional relationship of components and the like, an upper direction of a drawing is described as “up”, and a lower direction of the drawing is described as “down”. In the present specification, the concepts of “up” and “down” are not necessarily terms indicating a relationship with the direction of gravity.

### First Embodiment

A semiconductor memory device of the present embodiment includes a stacked film in which a plurality of silicon oxide layers having a film density of 2.3 g/cm³ or more and a plurality of conductive layers are alternately stacked one layer at a time in a first direction, and a memory pillar that penetrates the stacked film in the first direction in which a plurality of memory cells is provided.

A method for manufacturing a semiconductor memory device of the present embodiment, the method includes forming a stacked film in which a plurality of first layers containing silicon and a plurality of second layers containing silicon nitride are alternately stacked one layer at a time in a first direction, forming an opening that penetrates the stacked film and extends in the first direction, and forming a plurality of silicon oxide layers between each of the plurality of second layers by oxidizing the plurality of first layers.

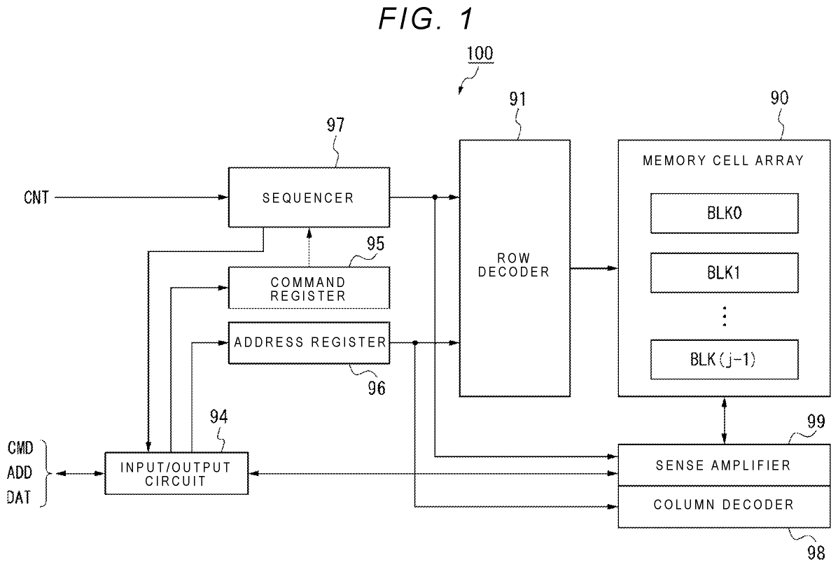

The overall configuration of the semiconductor memory device 100 will be described. The semiconductor memory device 100 according to the present embodiment is a NAND flash memory capable of storing data non-volatilely. FIG. 1 is a block diagram of a semiconductor memory device 100 according to the present embodiment.

The semiconductor memory device 100 includes a memory cell array 90, a row decoder 91, a column decoder 98, a sense amplifier 99, an input/output circuit 94, a command register 95, an address register 96, a sequencer (which is generally a control circuit) 97, and the like.

The memory cell array 90 includes j blocks BLK0 to BLK(j−1). j is an integer of 1 or more. Each of the plurality of blocks BLK includes a plurality of memory cell transistors. The memory cell transistor includes a memory cell configured to be electrically rewritten. The memory cell array 90 includes a plurality of bit lines, a plurality of word lines, a source line, and the like in order to control a voltage applied to the memory cell transistor. The specific configuration of the block BLK will be described later.

The row decoder 91 receives a row address from the address register 96 and decodes the row address. The row decoder 91 performs a selection operation of the word line or the like based on the decoded row address. The row decoder 91 transfers a plurality of voltages required for a write operation, a read operation, and an erasing operation to the memory cell array 90.

The column decoder 98 receives a column address from the address register 96 and decodes the column address. The column decoder 98 performs a selection operation of the bit line based on the decoded column address.

The sense amplifier 99 detects and amplifies the data read from the memory cell transistor into the bit line during the read operation. In addition, the sense amplifier 99 transfers the write data to the bit line during the write operation.

The input/output circuit 94 is connected to an external device (e.g., host device) via a plurality of input/output lines (e.g., DQ lines). The input/output circuit 94 receives a command CMD and an address ADD from the external device. The command CMD received by the input/output circuit 94 is sent to the command register 95. The address ADD received by the input/output circuit 94 is sent to the address register 96. The input/output circuit 94 transmits and receives data DAT to and from the external device.

The sequencer 97 receives a control signal CNT from the external device. The control signal CNT includes a chip enable signal CEn, a command latch enable signal CLE, an address latch enable signal ALE, a write enable signal WEn, a read enable signal REn, and the like. The “n” added to the signal name indicates the active low. The sequencer 97 controls the operation of the entire semiconductor memory device 100 based on the command CMD stored in the command register 95 and the control signal CNT.

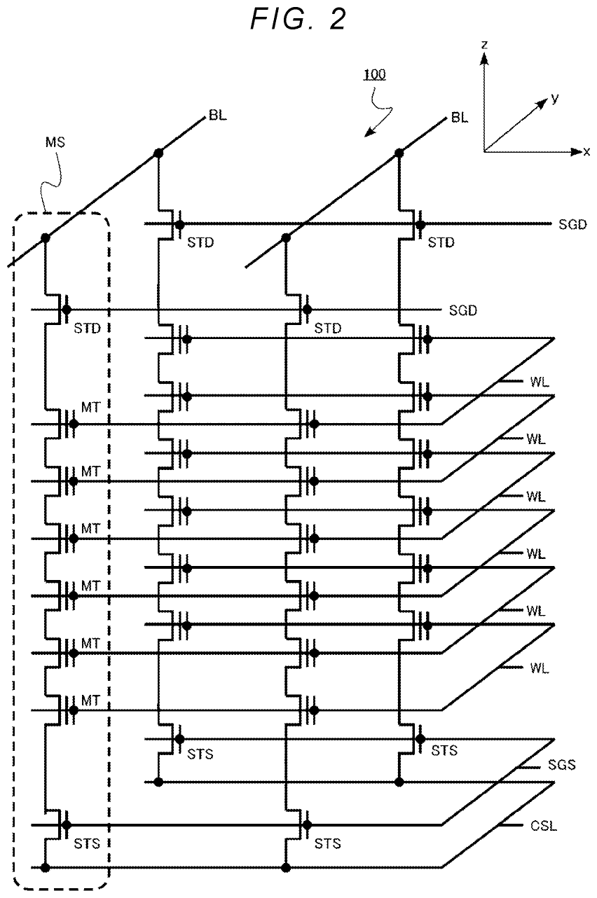

FIG. 2 is an equivalent circuit diagram of the semiconductor memory device 100 according to the present embodiment.

As shown in FIG. 2, the semiconductor memory device 100 includes a plurality of word lines WL, a common source line CSL, a source select gate line SGS, a plurality of drain select gate lines SGD, a plurality of bit lines BL, and a plurality of memory strings MS.

The memory string MS includes a source select transistor STS, a plurality of memory cell transistors MT, and a drain select transistor STD, which are connected in series between the common source line CSL and the bit line BL.

The number of word lines WL, the number of bit lines BL, the number of memory strings MS, and the number of drain select gate lines SGD are not limited to those in FIG. 2.

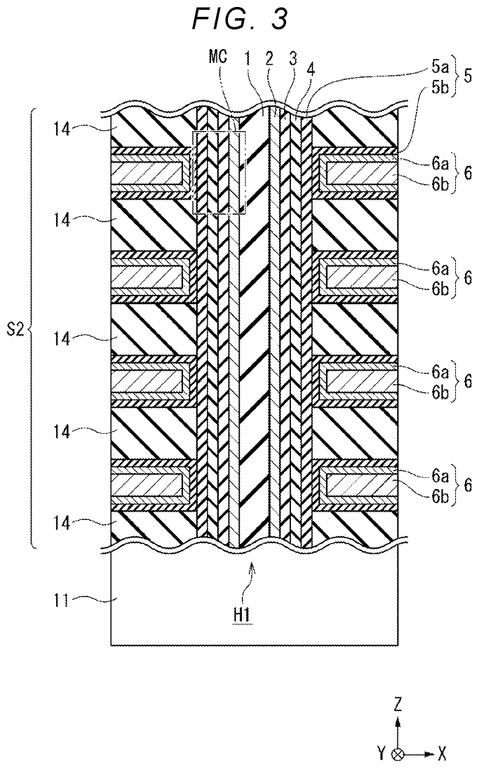

FIG. 3 is a schematic cross-sectional view of a main part of the semiconductor memory device 100 according to the present embodiment.

The substrate 11 is, for example, a semiconductor layer containing single crystal silicon. For example, a semiconductor wafer or an SOI wafer may be used as the substrate 11.

Here, an X direction, a Y direction that intersects perpendicularly to the X direction, and a Z direction that intersects perpendicularly to the X and Y directions are defined. The substrate 11 is provided parallel to the XY plane.

A plurality of first silicon oxide layers 14 and a plurality of conductive layers 6b are alternately stacked one layer at a time on the substrate 11 in the Z direction. Accordingly, the stacked film S2 is provided on the substrate 11.

The film density of the plurality of first silicon oxide layers 14 is 2.3 g/cm³ or more. For example, the film density may be 2.4 g/cm³.

The film density of the plurality of first silicon oxide layers 14 may be evaluated using, for example, X-ray reflectometry (XRR).

The film thickness of the plurality of first silicon oxide layers 14 in the Z direction is preferably 10 nm or more.

The hydrogen concentration of the plurality of first silicon oxide layers 14 is preferably 1×10²⁰ atoms/cm³ or less.

The memory pillar H1 penetrates the stacked film S2 in the Z direction. A core insulating film 1, a channel semiconductor layer 2, a tunnel insulating film 3, a charge storage film 4, and an insulating film 5a are provided in the memory pillar H1.

The core insulating film 1 is provided in the memory pillar H1. The core insulating film 1 contains silicon oxide, for example.

The channel semiconductor layer 2 is provided around the core insulating film 1 in the memory pillar H1. The channel semiconductor layer 2 functions as a channel of the memory pillar H1. The channel semiconductor layer 2 is a pillar containing a semiconductor material such as polysilicon.

The tunnel insulating film 3 is provided around the channel semiconductor layer 2. Although the tunnel insulating film 3 is insulating, it is an insulating film that allows current to flow when a predetermined voltage is applied. The tunnel insulating film 3 contains, for example, silicon oxynitride.

The charge storage film 4 is provided around the tunnel insulating film 3. The charge storage film 4 is a film containing a material capable of storing charges. The charge storage film 4 contains, for example, silicon nitride.

The insulating film 5a is provided around the charge storage film 4. The insulating film 5a contains, for example, silicon oxide. The film density of the insulating film 5a is less than the film density of the first silicon oxide layer 14, for example, less than 2.3 g/cm³.

The insulating film 5b, the barrier metal layer 6a, and the conductive layer 6b are provided between the first silicon oxide layers 14 adjacent to each other.

The insulating film 5b is provided around each of the barrier metal layers 6a (on the lower surface of each first silicon oxide layer 14, the upper surface of each first silicon oxide layer 14, and the side surface of the insulating film 5a). The insulating film 5b contains a metal insulating material such as aluminum oxide.

The barrier metal layer 6a is provided around each of the conductive layers 6b (on the lower surface of the upper insulating film 5b, the upper surface of the lower insulating film 5b, and the side surface of the insulating film 5b provided on the side surface of the insulating film 5a). The barrier metal layer 6a contains, for example, titanium nitride.

The conductive layer 6b is provided in the barrier metal layer 6a. The conductive layer 6b contains, for example, tungsten (W). The conductive layer 6b corresponds to the word line WL.

A memory cell MC is provided in each of portions of the memory pillar H1 facing the conductive layer 6b. A plurality of memory cells MC provided in one memory pillar H1 are provided in one memory string MS. Each memory cell MC includes a memory cell transistor MT.

In FIG. 3, one memory string MS of the memory strings MS shown in FIG. 2 is shown. The semiconductor memory device 100 includes a plurality of memory pillars H1, a plurality of memory cells MC being provided in each of the memory pillars H1.

In addition, a common source line CSL (not shown), a source select gate line SGS (not shown), and a plurality of source select transistors STS (not shown) are provided between the stacked film S2 and the substrate 11.

In addition, a plurality of drain select gate lines SGD (not shown), a plurality of bit lines BL (not shown), and a plurality of drain select transistors STD (not shown) are provided on the stacked film S2.

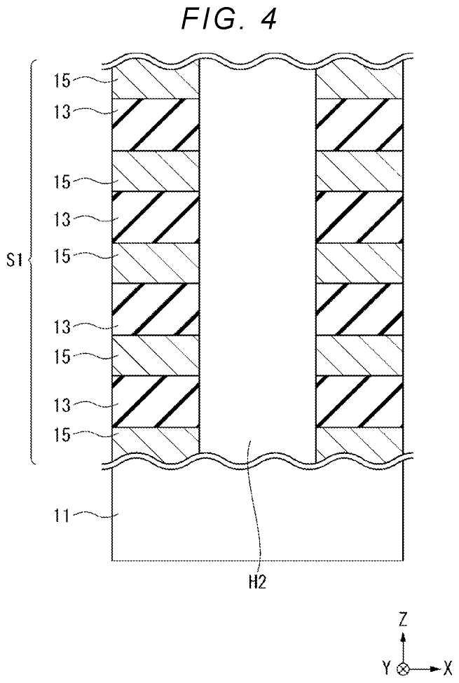

FIGS. 4 to 7 are schematic cross-sectional views showing the method for manufacturing a semiconductor memory device 100 according to the present embodiment.

The common source line CSL (not shown), the source select gate line SGS (not shown), and the plurality of source select transistors STS (not shown) are formed on the substrate 11.

Next, the plurality of first layers 15 containing silicon and the plurality of second layers 13 containing silicon nitride are formed by alternately stacking the first layers 15 and the second layers 13 one layer at a time in the Z direction, by a plasma-enhanced chemical vapor deposition (plasma CVD) method for example. As a result, the stacked film S1 is formed. Here, the plurality of first layers 15 contain silicon as a main component and are, for example, amorphous silicon layers. In other words, the plurality of first layers 15 each contain, for example, amorphous silicon.

Next, as shown in FIG. 4, an opening H2 that penetrates the stacked film S1 in the Z direction and that extends in the Z direction is formed by, for example, a reactive ion etching (RIE) method.

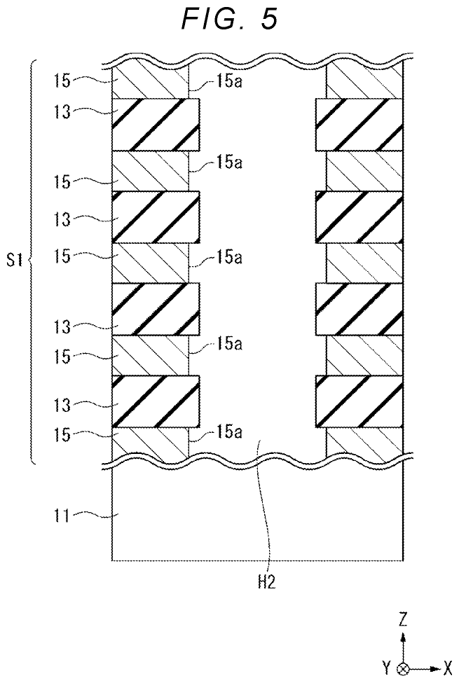

Next, as shown in FIG. 5, a part of each of the plurality of first layers 15 exposed in the opening H2 is removed by wet etching using an etchant including hydrofluoric acid. A recessed portion 15a is formed at each of the end portions of the plurality of first layers 15 exposed to the opening H2.

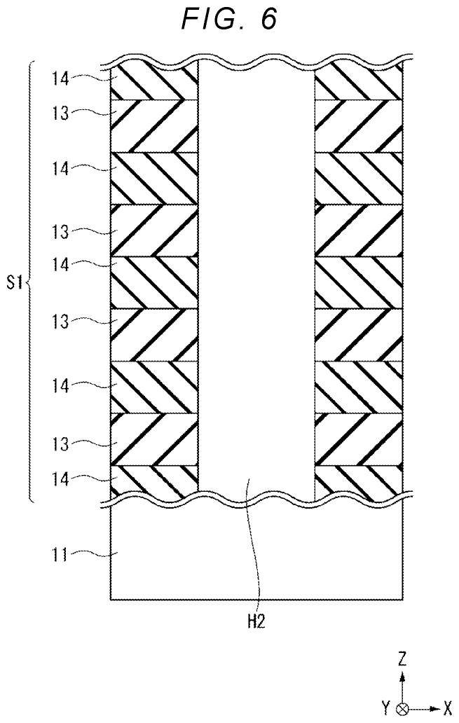

Next, as shown in FIG. 6, a first silicon oxide layer 14 is formed between each of the sets of adjacent ones of the second layers 13 by oxidizing the plurality of first layers 15. Due to the oxidation, the plurality of first silicon oxide layers 14 expand with respect to both the XY plane and the Z direction as compared with the plurality of first layers 15.

A length of any of the second layers 13 between any adjacent two of the plurality of openings H2 in the plane (XY plane) intersecting perpendicularly to the first direction is desirably 1.15 times or more and 1.35 times or less than a length of any of the first layers 15 between the respective adjacent two of the plurality of openings H2 in the plane intersecting perpendicularly to the first direction.

The oxidation of the plurality of first layers 15 is preferably wet oxidation (for example, H₂O annealing) under high pressure conditions. Here, the wet oxidation is performed, for example, by using a hydrogen gas and an oxygen gas and supplying water vapor (H₂O) generated by a combustion reaction of the hydrogen gas and the oxygen gas into a reaction chamber in which the semiconductor memory device 100 is manufactured.

A partial pressure of water vapor (H₂O) in the reaction chamber is preferably higher than the atmospheric pressure, and 25 atmospheres or less. The partial pressure of water vapor (H₂O) in the reaction chamber is even more preferably 5 atmospheres or more and 25 atmospheres or less. The partial pressure of water vapor (H₂O) in the reaction chamber is even more preferably yet 20 atmospheres or more and 25 atmospheres or less.

A time interval during which the wet oxidation is performed is preferably 10 minutes or longer and 1 hour or shorter. A temperature at which the wet oxidation is performed is preferably 750° C. or higher and 1000° C. or lower.

The film density of each of the plurality of first silicon oxide layers 14 formed by wet oxidation is preferably 2.3 g/cm³ or more.

The film thickness of each of the plurality of first silicon oxide layers 14 formed by wet oxidation in the Z direction is preferably 10 nm or more.

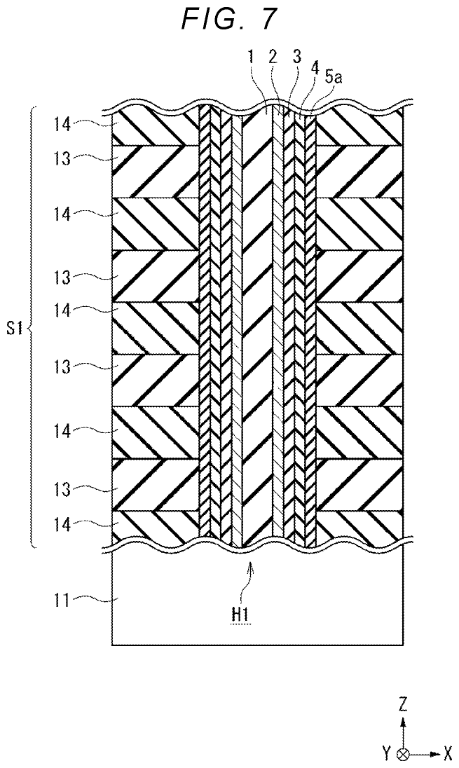

Next, as shown in FIG. 7, the insulating film 5a, the charge storage film 4, the tunnel insulating film 3, and a part of the channel semiconductor layer 2 are formed in the opening H2 in this order by, for example, an atomic layer deposition (ALD) method. Next, the insulating film 5a, the charge storage film 4, the tunnel insulating film 3, and a part of the channel semiconductor layer 2 are removed from the bottom of the opening H2 by, for example, etching. Next, the remainder of the channel semiconductor layer 2 and the core insulating film 1 are formed in the opening H2 in this order by, for example, an atomic layer deposition (ALD) method. As a result, the insulating film 5a, the charge storage film 4, the tunnel insulating film 3, the channel semiconductor layer 2, and the core insulating film 1 are formed in the opening H2 in this order.

Next, a slit (not shown) is formed in the stacked film S1. Next, a chemical solution such as phosphoric acid is supplied using such a slit, and a plurality of second layers 13 are removed. Next, the insulating film 5b, the barrier metal layer 6a, and the conductive layer 6b are formed in this order on the portion from which the plurality of second layers 13 are removed. As a result, the stacked film S2 is formed.

In addition, a plurality of drain select gate lines SGD (not shown), a plurality of bit lines BL (not shown), and a plurality of drain select transistors STD (not shown) are formed on the stacked film S2. As a result, the semiconductor memory device 100 of the present embodiment is manufactured.

Next, the operation and effect of the semiconductor memory device 100 of the present embodiment will be described.

In the semiconductor memory device 100 of the present embodiment, the insulating layer provided between each of conductive layers 6b is required to have high breakdown voltage. For example, when an insulating film having a high breakdown voltage is formed, the size of the semiconductor memory device 100 is reduced by thinning of the insulating layer. In addition, when an insulating film having a high breakdown voltage is formed, since dielectric breakdown is less likely to occur, a semiconductor memory device 100 having high reliability is manufactured.

As a comparative example, a silicon oxide layer formed by a plasma-enhanced chemical vapor deposition (plasma CVD) method is used as an insulating layer provided between each of the conductive layers 6b. However, the silicon oxide layer formed by the plasma CVD method has a low film quality, and thus it is difficult to achieve sufficient breakdown voltage.

Therefore, a semiconductor memory device 100 of the present embodiment includes a stacked film in which a plurality of first silicon oxide layers having a film density of 2.3 g/cm³ or more and a plurality of conductive layers are alternately stacked one layer at a time in a first direction, and includes a memory pillar that penetrates the stacked film in the first direction in which a plurality of memory cells is provided.

By using the plurality of first silicon oxide layers 14 having the film density of 2.3 g/cm³ or more as the insulating layer, the film quality of the insulating layer is improved. As a result, an insulating layer such as a silicon oxide layer formed by a thermal oxidation method is formed, which is a good insulating layer. Therefore, a semiconductor memory device 100 having high reliability is manufactured.

The film thickness of the plurality of each of the first silicon oxide layers 14 in the Z direction is preferably 10 nm or more. This is to maintain sufficient insulation between the adjacent conductive layers 6b.

The hydrogen concentration of each of the plurality of first silicon oxide layers 14 is preferably 1×10²⁰ atoms/cm³ or less. A layer having a low hydrogen concentration can be formed by the plurality of first silicon oxide layers 14 formed by the above-described manufacturing method.

A method for manufacturing a semiconductor memory device 100 of the present embodiment includes forming a stacked film in which a plurality of first layers containing silicon and a plurality of second layers containing silicon nitride are alternately stacked in a first direction, forming an opening that penetrates the stacked film and extends in the first direction, and forming a plurality of first silicon oxide layers between each of the plurality of second layers by oxidizing the plurality of first layers.

By forming a plurality of first layers 15 containing silicon and then oxidizing the plurality of first layers 15, an insulating film having a high breakdown voltage is formed.

The oxidation of the plurality of first layers 15 containing silicon as described above can be performed by wet oxidation. In this wet oxidation, it is preferable to use water vapor (H₂O) generated by a combustion reaction of hydrogen gas and oxygen gas in order to form a high-quality film.

When the wet oxidation is performed, the partial pressure of the water vapor (H₂O) in the reaction chamber in which the semiconductor memory device 100 is manufactured is preferably higher than the atmospheric pressure and 25 atmospheres or less. By using such a water vapor having a high-partial pressure, the plurality of first layers 15 containing silicon is oxidized and the plurality of first silicon oxide layers 14 is formed. The partial pressure of the water vapor (H₂O) in the reaction chamber is even more preferably 5 atmospheres or more and 25 atmospheres or less, in order to form a plurality of first silicon oxide layers 14 having a higher quality. In addition, the partial pressure of the water vapor (H₂O) in the reaction chamber is even more preferably yet 20 atmospheres or more and 25 atmospheres or less, in order to form a plurality of first silicon oxide layers 14 having a higher quality yet.

A time interval during which the wet oxidation is performed is preferably 10 minutes or longer and 1 hour or shorter. When the wet oxidation is performed for a time shorter than 10 minutes, it is not possible to sufficiently oxidize the plurality of first layers 15 containing silicon. In addition, when the wet oxidation is performed for a time longer than 1 hour, the time is too long, and thus the productivity of the semiconductor memory device 100 is reduced.

After the opening H2 is formed, it is preferable to remove a part of each of the plurality of first layers 15 exposed in the opening H2 before the oxidation of the plurality of first layers 15 is performed. Since the plurality of first layers 15 expand in the XY plane and the Z direction due to oxidation, the plurality of first layers 15 protrude into the opening H2. This protruding portion may hinder the formation of the film contained in the memory pillar H1. Therefore, before oxidizing the plurality of first layers 15, a part of each of the plurality of first layers 15 is removed to an extent that it does not hinder the formation of the film contained in the memory pillar H1. This includes removing from each of the plurality of first layers 15, parts that are exposed to any of a plurality of openings H2 (thus removing parts on both sides of the first layers 15 in the X direction).

In addition, a length of any of the second layers 13 between any adjacent two of the plurality of openings H2 in the plane (XY plane) intersecting perpendicularly to the first direction is desirably 1.15 times or more and 1.35 times or less than a length of any of the first layers 15 between the respective adjacent two of the plurality of openings H2 in the plane intersecting perpendicularly to the first direction. This is to ensure that the side surface of the opening H2 becomes sufficiently smooth in the Z direction to an extent that it does not hinder the formation of the memory pillar H1 due to the expansion caused by the oxidation of the plurality of first layers 15.

According to the semiconductor memory device 100 of the present embodiment, it is possible to provide a highly integrated semiconductor memory device 100.

### Second Embodiment

The semiconductor memory device 100 of the present embodiment is different from the semiconductor memory device 100 of the first embodiment in that the semiconductor memory device 100 of the present embodiment further includes a plurality of third layers provided between each of the plurality of conductive layers and the memory pillar that contain silicon oxynitride. Here, description of content that overlaps with the first embodiment will be omitted.

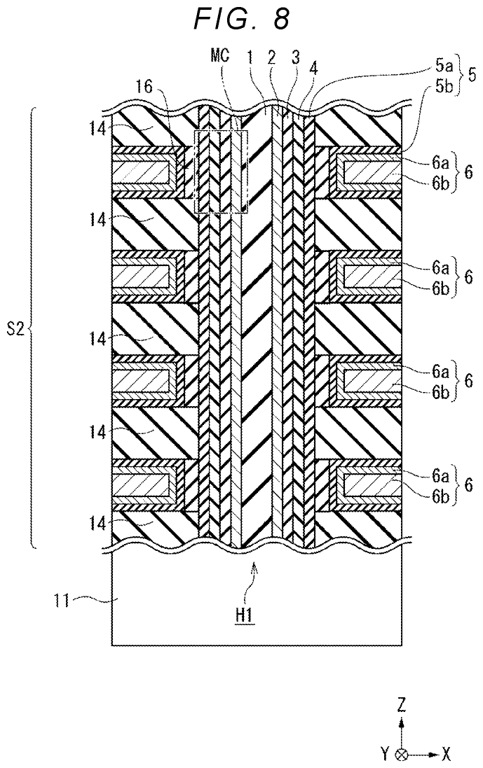

FIG. 8 is a schematic cross-sectional view of a main part of the semiconductor memory device 100 according to the present embodiment. The third layers 16 are provided between each of the conductive layers 6b and the memory pillar H1. The third layer 16 contains silicon oxynitride.

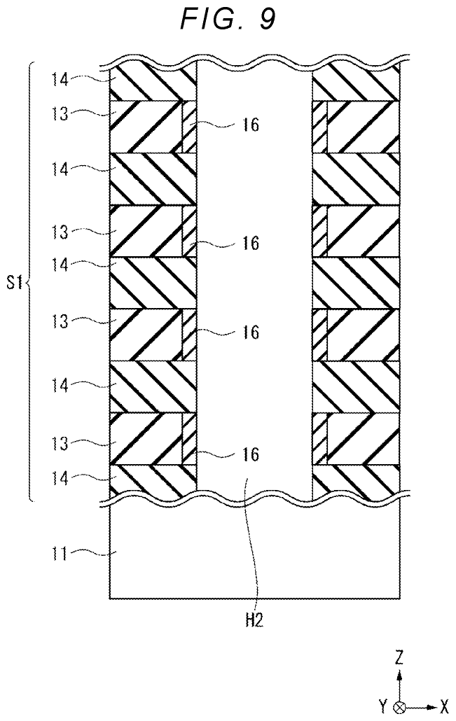

FIG. 9 is a schematic cross-sectional view showing the method for manufacturing a semiconductor memory device 100 according to the present embodiment. By oxidizing the plurality of first layers 15, the plurality of third layers 16 each containing silicon oxynitride are formed between each of the second layers 13 and the opening H2 when the plurality of first silicon oxide layers 14. The plurality of third layers 16 are formed by oxidizing the portions of the second layer 13 exposed in the opening H2.

The semiconductor memory device 100 of the present embodiment provides a highly integrated semiconductor memory device 100.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked film in which a plurality of silicon oxide layers, one of which having a film density of 2.3 g/cm³ or more, and a plurality of conductive layers, are alternately stacked in a first direction; and
a memory pillar that penetrates the stacked film in the first direction, wherein a plurality of memory cells is provided in the memory pillar.

2. The semiconductor memory device according to claim 1, wherein a film thickness of one of the plurality of silicon oxide layers in the first direction is 10 nm or more.

3. The semiconductor memory device according to claim 1, wherein a hydrogen concentration of one of the plurality of silicon oxide layers is 1×10²⁰ atoms/cm³ or less.

4. The semiconductor memory device according to claim 1, further comprising:
a plurality of third layers provided respectively between the plurality of conductive layers and the memory pillar, one of the plurality of third layers containing silicon oxynitride.

5. The semiconductor memory device according to claim 1, further comprising:
a plurality of memory pillars that each penetrates the stacked film and extends in the first direction, wherein a plurality of memory cells is provided in each of the memory pillars.

6. The semiconductor memory device according to claim 1, wherein the memory pillar includes a core insulating film, a channel semiconductor layer around the core insulating film, a tunnel insulating film around the channel semiconductor layer, a charge storage film around the tunnel insulating film, and an insulating film around the charge storage film.

7. The semiconductor memory device according to claim 6, wherein the core insulating film contains silicon oxide, the channel semiconductor layer contains polysilicon, the tunnel insulating film contains silicon oxynitride, the charge storage film contains silicon nitride, and the insulating film around the charge storage film contains silicon oxide.

8. The semiconductor memory device according to claim 1, wherein a barrier metal layer is provided around one of the plurality of conductive layers, and an insulating film is provided around the barrier metal layer.

9. The semiconductor memory device according to claim 8, wherein the barrier metal layer contains titanium nitride, and the insulating film contains aluminum oxide.

10. A method for manufacturing a semiconductor memory device, the method comprising:
forming a stacked film in which a plurality of first layers containing silicon and a plurality of second layers containing silicon nitride are alternately stacked in a first direction;
forming an opening that penetrates the stacked film and that extends in the first direction; and
forming a silicon oxide layer between a set of adjacent ones of the plurality of second layers by oxidizing a first layer that is between the set of adjacent ones of the plurality of second layers.

11. The method for manufacturing a semiconductor memory device according to claim 10, wherein the oxidizing is a wet oxidation.

12. The method for manufacturing a semiconductor memory device according to claim 11, wherein the wet oxidation is performed using a hydrogen gas and an oxygen gas.

13. The method for manufacturing a semiconductor memory device according to claim 11, wherein when the wet oxidation is performed on the first layer between the set of adjacent ones of the plurality of second layers, a partial pressure of water vapor (H₂O) in a reaction chamber in which the semiconductor memory device is manufactured is higher than atmospheric pressure and atmospheres or less.

14. The method for manufacturing a semiconductor memory device according to claim 11, wherein a time interval during which the wet oxidation is performed is 10 minutes or longer and 1 hour or shorter.

15. The method for manufacturing a semiconductor memory device according to claim 10, wherein a film density of the silicon oxide layer is 2.3 g/cm³ or more.

16. The method for manufacturing a semiconductor memory device according to claim 10, wherein a film thickness of the silicon oxide layer in the first direction is 10 nm or more.

17. The method for manufacturing a semiconductor memory device according to claim 10, wherein a hydrogen concentration of the silicon oxide layer is 1×10²′ atoms/cm³ or less.

18. The method for manufacturing a semiconductor memory device according to claim 10, further comprising:
forming a third layer containing silicon oxynitride by oxidizing the first layer between the set of adjacent ones of the plurality of second layers.

19. The method for manufacturing a semiconductor memory device according to claim 10, further comprising:
removing from the first layer between the set of adjacent ones of the plurality of second layers, a part exposed to the opening, after forming the opening and before the oxidizing the first layer between the set of adjacent ones of the plurality of second layers.

20. The method for manufacturing a semiconductor memory device according to claim 19, further comprising:
forming a plurality of the openings that each penetrates the stacked film and extends in the first direction; and
removing from one of the plurality of first layers, parts thereof that are exposed to any of the plurality of openings,
wherein a length of a second layer that is between an adjacent two of the plurality of openings in a plane intersecting the first direction, is 1.15 times or more and 1.35 times or less than a length of a first layer that is between the adjacent two of the plurality of openings in the plane.
